(19) United States
(12) Patent Application Publication
(10) Pub. No.: US 2021/0183559 A1
(43) Pub. Date: Jun. 17, 2021

(54) CURRENT INTRODUCTION TERMINAL STRUCTURE AND ELECTROMAGNET DEVICE

(71) Applicants: KABUSHIKI KAISHA TOSHIBA, Tokyo (JP); TOSHIBA ENERGY SYSTEMS & SOLUTIONS CORPORATION, Kawasaki-shi (JP)

(72) Inventors: Kazuya SAWADA, Katsushika (JP); Kunihiko KINUGASA, Yokohama (JP); Tomofumi ORIKASA, Yokohama (JP); Takayuki KOBAYASHI, Itabashi (JP)

(73) Assignees: KABUSHIKI KAISHA TOSHIBA, Tokyo (JP); TOSHIBA ENERGY SYSTEMS & SOLUTIONS CORPORATION, Kawasaki-shi (JP)

(21) Appl. No.: 17/188,255

(22) Filed: Mar. 1, 2021

Related U.S. Application Data
(63) Continuation of application No. PCT/JP2019/038712, filed on Oct. 1, 2019.

(30) Foreign Application Priority Data
Oct. 31, 2018 (JP) 2018-204634

(51) Int. Cl. H01F 27/16; H01F 27/28; H01F 27/02; H01F 7/20

(52) U.S. Cl. CPC H01F 27/16; H01F 27/2823; H01F 2007/062; H01F 7/20; H01F 27/025

(57) ABSTRACT

The present invention improves cooling efficiency of a conductive member, which is formed by bundling a plurality of wires and to which electric current is led from a current introduction terminal.

A current introduction terminal structure 10, in which electric current is led from a current introduction terminal 12 to a conductive member 13 formed by bundling a plurality of wires 34, is configured in such a manner that the conductive member 13 and the current introduction terminal 12 electrically connected to this conductive member 13 are disposed in a casing 14 for storing cooling water W and are immersed in the cooling water W.

### CROSS-REFERENCE TO RELATED APPLICATIONS

This application is a Continuation Application of No. PCT/JP2019/038712, filed on Oct. 1,2019, and the PCT application is based upon and claims the benefit of priority from Japanese Patent Application No. 2018-204634, filed on Oct. 31,2018, the entire contents of which are incorporated herein by reference.

### TECHNICAL FIELD

Embodiments of the present invention relate to a current introduction terminal structure, which has a current introduction terminal to be electrically connected to a conductive member formed by bundling a plurality of wires, and an electromagnet device that uses this current introduction terminal structure.

### BACKGROUND

FIG. 4 is a cross-sectional view schematically illustrating a conventional current introduction terminal structure. In this conventional current introduction terminal structure 100, a cooling-water pipe 104 is coaxially disposed inside a tubular current introduction terminal 101 in which one side is closed, a conductive member 103 is electrically connected to the tip of the current introduction terminal 101 via a crimp terminal 102, and a cooling-water supply-pipe 106 is connected to the cooling-water pipe 104 via a cooling-water joint 105. Further, the conductive member 103 is electrically connected to an electromagnet that is the destination of current supply.

The current introduction terminal 101 is fixed to a connection flange 108 via an insulating member 107 by brazing, and the connection flange 108 is fastened to an electromagnet housing 110 with a bolt 109. Further, a second current introduction member 112 is fixed to the current introduction terminal 101 by brazing, and as shown in FIG. 5, a first current introduction member 111 is fastened to the second current introduction member 112 with bolts 113 and hexagon nuts 114.

The conductive member 103 is formed by bundling a plurality of wires 115 made of a conductive material, and is fastened to the closed tip of the current introduction terminal 101 with a bolt 116 via the crimp terminal 102 as described above. The conductive member 103 is disposed in an internal space 122 which is surrounded by the electromagnet housing 110 and a housing lid 121 for closing the opening of the electromagnet housing 110. Electric current from a power supply (not shown) is led to the conductive member 103 via the first current introduction member 111, the second current introduction member 112, the current introduction terminal 101, and the crimp terminal 102, and is supplied from this conductive member 103 to the electromagnet that is the destination of current supply.

The cooling-water pipe 104 is disposed in the tubular current introduction terminal 101 such that the inside of the cooling-water pipe 104 serves as a cooling-water supply-channel 117 and the space between the cooling-water pipe 104 and the current introduction terminal 101 serves as a cooling-water drainage-channel 118. Further, the cooling-water pipe 104 is fixed to the cooling-water joint 105 by caulking, and the cooling-water supply-pipe 106 is also fixed to the cooling-water joint 105 by caulking. Thereby, the cooling-water pipe 104 in the current introduction terminal 101 is connected to the cooling-water supply-pipe 106 made of an insulating material via the cooling-water joint 105.

Further, the current introduction terminal 101 is fixed to the cooling-water joint 119 by screwing or brazing, and a cooling-water drain-pipe 120 and the cooling-water pipe 104 are fixed to the cooling-water joint 119 by caulking. Consequently, the cooling-water drainage-channel 118 between the cooling-water pipe 104 and the current introduction terminal 101 is connected to the cooling-water drain-pipe 120 made of an insulating material via the cooling-water joint 119.

Thus, the cooling water from the cooling-water supply-pipe 106 flows through the cooling-water supply-channel 117 in the cooling-water pipe 104 via the cooling-water joint 105, then reverses at the tip of the cooling-water pipe 104 so as to flow into the cooling-water drainage-channel 118, and is drained from the cooling-water drain-pipe 120 via the cooling-water joint 119. In this manner, the conductive member 103 formed by bundling a plurality of wires 115 is indirectly cooled by the cooling water via the crimp terminal 102 and the current introduction terminal 101.

### PRIOR ART DOCUMENT

### Patent Document

[Patent Document 1] JP 2013-115281 A

[Patent Document 2] Japanese Unexamined Utility Model Application Publication No. H04-136897

### SUMMARY

### Problems to be Solved by Invention

As described above, the conductive member 103 formed by bundling a plurality of wires 115 is indirectly cooled by the cooling water flowing inside the current introduction terminal 101 via the crimp terminal 102 and the current introduction terminal 101. Thus, cooling of the conductive member 103 depends on the thermal conductivity of the crimp terminal 102 and the current introduction terminal 101. Hence, even if the diameter of each of the current introduction terminal 101 and the cooling-water pipe 104 is increased to increase the amount of the cooling water, the cooling efficiency of the conductive member 103 is insufficient in some cases and there is a possibility that a large electric current cannot be supplied to the conductive member 103.

In view of the above-described problem, an object of embodiments of the present invention is to provide a current introduction terminal structure and an electromagnet device, both of which can improve cooling efficiency of a conductive member, which is formed by bundling a plurality of wires and to which electric current is led from a current introduction terminal.

### Solution to Problem

A current introduction terminal structure according to one embodiment of the present invention has a structure in which electric current is led from a current introduction terminal to a conductive member formed by bundling a plurality of wires, and is configured in such a manner that the conductive member and the current introduction terminal electrically connected to the conductive member are disposed in a casing for storing cooling water and are immersed in the cooling water.

An electromagnet device according to one embodiment of the present invention is configured in such a manner that the above-described current introduction terminal structure is disposed between an electromagnet and a power source to electrically connect the electromagnet to the power source.

### BRIEF DESCRIPTION OF DRAWINGS

FIG. 1 is a cross-sectional view schematically illustrating a current introduction terminal structure according to one embodiment.

FIG. 2 is a view on the arrow II in FIG. 1.

FIG. 3 is a cross-sectional view schematically illustrating an electromagnet device according to one embodiment.

FIG. 4 is a cross-sectional view schematically illustrating a conventional current introduction terminal structure.

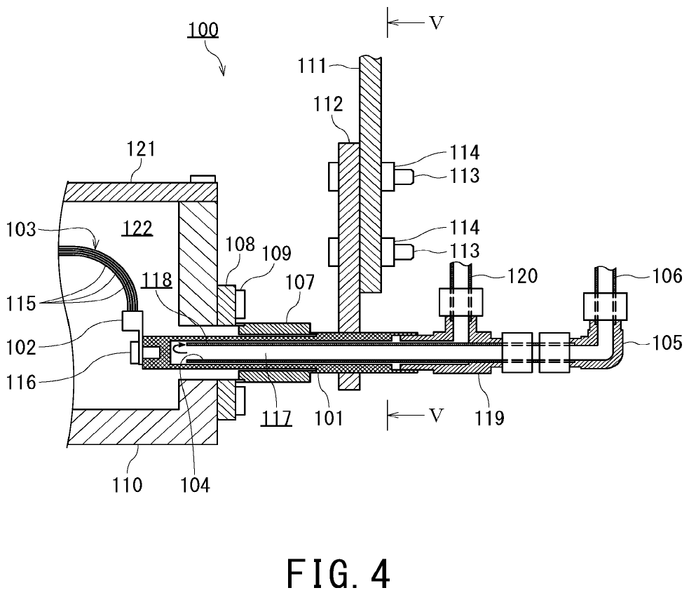

FIG. 5 is a view on the arrow V in FIG. 4.

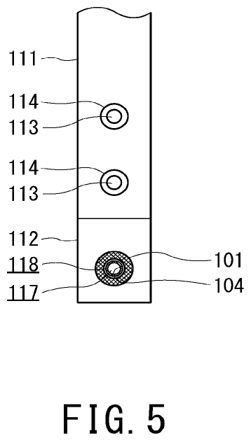

### DETAILED DESCRIPTION

Hereinafter, embodiments of the present invention will be described by referring to the drawings.

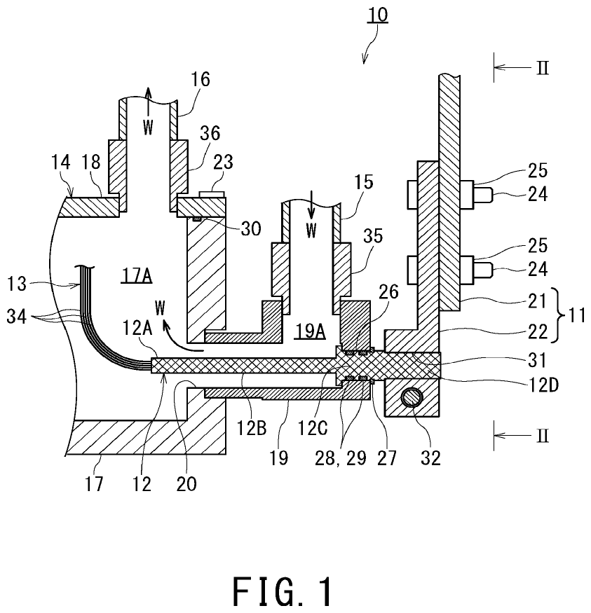

FIG. 1 is a cross-sectional view schematically illustrating a current introduction terminal structure according to one embodiment. The current introduction terminal structure 10 shown in FIG. 1 leads electric current from a power source (not shown) to a current introduction terminal 12 via a current introduction member 11, and supplies the electric current to, for example, an electromagnet (not shown), which is the destination of current supply, via a conductive member 13 electrically connected to the current introduction terminal 12. The current introduction terminal 12 and the conductive member 13 are disposed in a casing 14 in which cooling water W such as pure water having electric non-conductance is stored (for example, filled), and a cooling-water supply-pipe 15 and a cooling-water drain-pipe 16 are attached to the casing 14.

The casing 14 includes: an electromagnet housing 17 as a casing body for accommodating an electromagnet (not shown); a housing lid 18 that closes the opening of the electromagnet housing 17; and a connection flange 19 as a connecting member to be fixed and attached to the electromagnet housing 17 by screwing or an adhesive. An internal space 19A of the connection flange 19 communicates with an internal space 17A of the electromagnet housing 17 by a communication port 20 formed in the electromagnet housing 17. Further, the housing lid 18 is fastened to the electromagnet housing 17 with a bolt 23. The internal space 17A of the electromagnet housing 17 is kept water-sealed by an O-ring 30 interposed between the electromagnet housing 17 and the housing lid 18. In particular, the electromagnet housing 17 is made of an insulating material.

The current introduction member 11 includes a first current introduction member 21 and a second current introduction member 22, both of which are made of a conductive material. The first current introduction member 21 is electrically connected to the power supply side. Further, the first current introduction member 21 is fastened to the second current introduction member 22 with, for example, bolts 24 and hexagon nuts 25 so as to be fixed. The second current introduction member 22 is electrically connected to the current introduction terminal 12 as described below, and thereby, the electric current from the power supply is led to the current introduction terminal 12 via the first current introduction member 21 and the second current introduction member 22.

The current introduction terminal 12 is solidly composed of a conductive material and has a tip portion 12A, a main body portion 12B, a base end portion 12C, and a base-end connecting portion 12D. The base end portion 12C of the current introduction terminal 12 is fitted into an interdigitation hole 26, which is formed so as to penetrate the connection flange 19, and is fixed to the connection flange 19 with a C-shaped retaining ring 27. Further, one or a plurality of peripheral grooves 28 are formed on the outer periphery of the base end portion 12C of the current introduction terminal 12, and an O-ring 29 is attached to the peripheral groove (s) 28. The O-ring 29 contacts the inner surface of the interdigitation hole 26 of the connection flange 19, and thereby, the internal space 19A of the connection flange 19 is kept water-sealed.

The base end portion 12C of the current introduction terminal 12 is fixed to the connection flange 19. Accordingly, the tip portion 12A and the main body portion 12B of the current introduction terminal 12 are disposed in the internal space 19A of the connection flange 19, the communication port 20 of the electromagnet housing 17, and the internal space 17A of the electromagnet housing 17 so as to be fully immersed in the cooling water W that does not conduct electricity. Further, the base-end connecting portion 12D of the current introduction terminal 12 is disposed outside the connection flange 19.

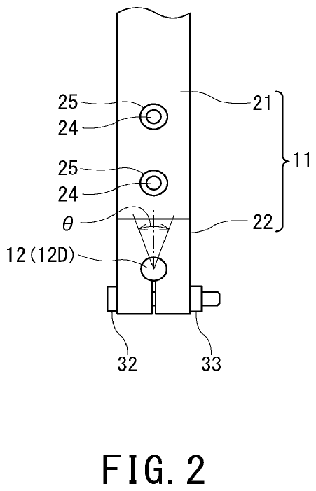

The base-end connecting portion 12D of the current introduction terminal 12 is inserted into a connection hole 31 formed in the second current introduction member 22, and is fastened to the second current introduction member 22 with the bolt 32 and the hexagon nut 33 shown in FIG. 2. As a result, the current introduction terminal 12 is electrically connected to the second current introduction member 22. When the bolt 32 and the hexagon nut 33 are loosened, under the state where the tip portion 12A and the main body portion 12B of the current introduction terminal 12 and the conductive member 13 described below are fully immersed in the cooling water W in the internal space 17A of the electromagnet housing 17 and the internal space 19A of the connection flange 19, the second current introduction member 22 is configured such that its mounting angle e can be adjusted with respect to the current introduction terminal 12 with the base-end connecting portion 12D of the current introduction terminal 12 as the rotation axis.

In addition, the base-end connecting portion 12D of the current introduction terminal 12 is fastened to the second current introduction member 22 with the bolt 32 and the hexagon nut 33. Consequently, under the state where the tip portion 12A and the main body portion 12B of the current introduction terminal 12 and the conductive member 13 described below are fully immersed in the cooling water W in the internal space 17A of the electromagnet housing 17 and the internal space 19A of the connection flange 19, the second current introduction member 22 is detachably attached to the current introduction terminal 12.

The conductive member 13 is formed by bundling a plurality of wires 34 made of a conductive material. This conductive member 13 is electrically connected to the tip portion 12A of the current introduction terminal 12 by, for example, brazing. The conductive member 13 is also electrically connected to an electromagnet (not shown) which is the destination of current supply. Thus, the electric current from the power supply is led to the conductive member 13 via the first current introduction member 21, the second current introduction member 22, and the current introduction terminal 12, and is supplied from this conductive member 13 to the destination of current supply (for example, the electromagnet). Further, the conductive member 13 is disposed in the internal space 17A of the electromagnet housing 17 and is fully immersed in the cooling water W filled in the internal space 17A.

The cooling-water supply-pipe 15 is connected to the connection flange 19 via a cooling-water joint 35. Further, the cooling-water drain-pipe 16 is connected to the housing lid 18 via a cooling-water joint 36. The cooling-water joint 35 is fixed to the connection flange 19 by, for example, screwing. The cooling-water joint 36 is fixed to the housing lid 18 by, for example, screwing. The cooling-water supply-pipe 15 is fixed to the cooling-water joint 35 by, for example, caulking. The cooling-water drain-pipe 16 is fixed to the cooling-water joint 36 by, for example, caulking. Of these, the cooling-water supply-pipe 15 and the cooling-water drain-pipe 16 are composed of an insulating material.

The cooling water W supplied from the cooling-water supply-pipe 15 flows into the internal space 19A of the connection flange 19 via the cooling-water joint 35, passes through the communication port 20 of the electromagnet housing 17 so as to flow into the internal space 17A of the electromagnet housing 17, and directly cools the current introduction terminal 12 and the conductive member 13. The cooling water W after cooling these current introduction terminal 12 and conductive member 13 is drained to the outside from the cooling-water drain-pipe 16 via the cooling-water joint 36. Since the tip portion 12A and the main body portion 12B of the current introduction terminal 12 are disposed in the internal space 19A of the connection flange 19, the base-end connecting portion 12D of the current introduction terminal 12, which becomes particularly hot, is efficiently cooled by the low-temperature cooling water that has flowed from the cooling-water supply-pipe 15 through the cooling-water joint 35 into the internal space 19A of the connection flange 19.

Since it is configured as described above, according to the present embodiment, the following effects (1) to (3) are obtained.

(1) The conductive member 13 formed by bundling a plurality of wires 34 and the current introduction terminal 12 electrically connected to this conductive member 13 are fully immersed in the cooling water W filled in each of the internal space 17A of the electromagnet housing 17 and the internal space 19A of the connection flange 19, and thus, are directly cooled by the cooling water W. Hence, the cooling efficiency of the conductive member 13 can be particularly improved. Even if the electric current to be supplied to the conductive member 13 is a large current, damage due to heat of the conductive member 13 can be avoided.

(2) The tip portion 12A and the main body portion 12B of the current introduction terminal 12 are disposed in the internal space 19A of the connection flange 19 and in the communication port 20 of the electromagnet housing 17. Further, after the cooling water W sequentially flows from the cooling-water supply-pipe 15 to the internal space 19A of the connection flange 19 and the communication port 20 of the electromagnet housing 17, the cooling water W flows sequentially to the internal space 17A of the electromagnet housing 17 and the cooling-water drain-pipe 16. As a result, the current introduction terminal 12 can be efficiently and directly cooled by the cooling water W in a low-temperature state, and the cooling efficiency of the current introduction terminal 12 can be improved.

(3) Under the state where the current introduction terminal 12 and the conductive member 13 are fully immersed in the cooling water W in the internal space 17A of the electromagnet housing 17 and the internal space 19A of the connection flange 19 so as to be directly cooled, the second current introduction member 22 is configured to be adjustable in mounting angle θ with respect to the current introduction terminal 12, and the second current introduction member 22 is detachably attached to the current introduction terminal 12. Thus, maintenance of the current introduction terminal structure 10 can be facilitated.

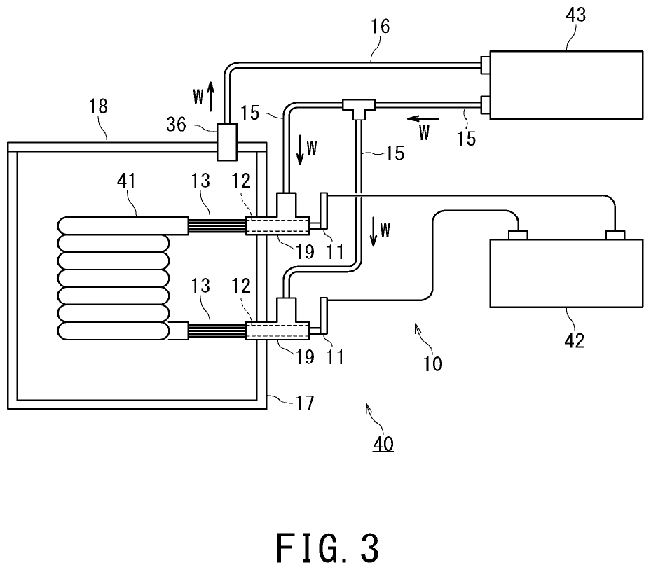

The current introduction terminal structure 10 according to the above-described embodiment can be applied to, for example, an electromagnet device shown in FIG. 3. FIG. 3 is across-sectional view schematically illustrating the electromagnet device according to one embodiment. In FIG. 3, the same components as those in FIG. 1 are denoted by the same reference signs to simplify or omit description of the configuration.

The electromagnet device 40 shown in FIG. 3 includes: an electromagnet 41; the electromagnet housing 17 that houses this electromagnet 41; and the current introduction terminal structure 10 that is disposed in this electromagnet housing 17 and is electrically connected to a power supply 42 and the electromagnet 41 so as to lead electric current. In this electromagnet device 40, the cooling water W such as pure water having electric non-conductance from a cooling-water circulation device 43 cools the current introduction terminal 12 via the cooling-water supply-pipe 15 and is led to the inside of the electromagnet housing 17, and the cooling water in the electromagnet housing 17 is returned to the cooling water circulation device 43 via the cooling-water drain-pipe 16. This structure can provide an electromagnet device that exhibits the above-described effects (1) to (3) similarly to the above-described embodiment.

While certain embodiments have been described, these embodiments have been presented by way of example only, and are not intended to limit the scope of the inventions. These embodiments maybe embodied in a variety of other forms, and various omissions, substitutions, and changes may be made without departing from the spirit of the inventions. These embodiments and their modifications are included in the accompanying claims and their equivalents as well as included in the scope and gist of the inventions.

1. A current introduction terminal structure in which electric current is led from a current introduction terminal to a conductive member formed by bundling a plurality of wires,
wherein the current introduction terminal structure is configured in such a manner that the conductive member and the current introduction terminal electrically connected to the conductive member are disposed in a casing for storing cooling water and are immersed in the cooling water.

2. The current introduction terminal structure according to claim 1, wherein:
the casing includes a casing body and a connecting member that is attached to the casing body and connects a cooling-water supply-pipe; and
the current introduction terminal is disposed at a communication port that communicates an internal space of the casing body and an internal space of the connecting member in such a manner that the cooling water from the cooling-water supply-pipe flows into the internal space of the casing body from the communication port through the internal space of the connecting member.

3. The current introduction terminal structure according to claim 1, wherein:
a current introduction member configured to lead electric current from a side of a power supply to the current introduction terminal is attached to the current introduction terminal; and
the current introduction member is configured to be adjustable in mounting angle with respect to the current introduction terminal under a state where a conductive member and the current introduction terminal are immersed in the cooling water in the casing.

4. The current introduction terminal structure according to claim 1, wherein:
a current introduction member configured to lead electric current from a side of a power supply to the current introduction terminal is attached to the current introduction terminal; and
the current introduction member is configured to be detachable from the current introduction terminal under a state where a conductive member and the current introduction terminal are immersed in the cooling water in the casing.

5. The current introduction terminal structure according to claim 1, wherein the cooling water is pure water that does not conduct electricity.

6. An electromagnet device wherein the current introduction terminal structure according to claim 1 is configured to electrically connect an electromagnet to a power source by being disposed between the electromagnet and the power source.
